(19) United States
(12) Patent Application Publication
(10) Pub. No.: US 2025/0015179 A1
(43) Pub. Date: Jan. 9, 2025

(54) SEMICONDUCTOR STRUCTURE AND METHOD FOR FABRICATING THE SAME

(71) Applicant: UNITED MICROELECTRONICS CORP., Hsinchu (TW)

(72) Inventor: Zong-Han LIN, Tainan City (TW)

(21) Appl. No.: 18/231,261

(22) Filed: Aug. 8, 2023

(30) Foreign Application Priority Data
Jul. 3, 2023 (CN) 202310802694.X

(51) Int. Cl. H01L 29/78; H01L 21/8234; H01L 27/088; H01L 29/10; H01L 29/423; H01L 29/66

(52) U.S. Cl. CPC H01L 29/7816; H01L 21/823456; H01L 21/823462; H01L 27/088; H01L 29/1095; H01L 29/42368; H01L 29/42376; H01L 29/66681

(57) ABSTRACT

A semiconductor structure and a method for fabricating the same are provided. The semiconductor structure includes a substrate, a source region, a drain region and a gate structure. The source region is located in the substrate. The drain region is located in the substrate. The gate structure is disposed on the substrate and located between the source region and the drain region, and includes a first sub-gate structure and a second sub-gate structure. The first sub-gate structure is adjacent to the source region and includes a first sub-gate insulating layer. The second sub-gate structure is adjacent to the drain region and includes a second sub-gate insulating layer. The second sub-gate insulating layer and the first sub-gate insulating layer are separated from each other. The first sub-gate insulating layer has a first thickness, and the second sub-gate insulating layer has a second thickness greater than the first thickness.

This application claims the benefit of People's Republic of China patent application Serial No. 202310802694.X, filed Jul. 3, 2023, the invention of which are incorporated by reference herein in its entirety.

### TECHNICAL FIELD

This disclosure relates to a semiconductor structure and a method for fabricating the same, in particular to a semiconductor structure including a separated gate and a method for fabricating the same.

### BACKGROUND

With the development of integrated circuit technology, composite semiconductor structures with different transistors have become one of the most important structures in integrated circuits. In a composite semiconductor structure, different transistors are required to provide different critical voltages.

For example, for a transistor that is subjected to a higher voltage, a thicker gate insulating layer is usually used to avoid the electrical breakdown of other core areas which may not withstand the high voltage. However, a gate insulating layer that is too thick does not allow for the desired switching current. In addition, as the critical dimensions of semiconductor structures shrink, the integrated circuits become denser and the process steps more complex.

### SUMMARY

This disclosure relates to a semiconductor structure and a method for fabricating the same, capable of withstanding high voltage and having better electrical performance, and solving the problems of flatness and high/low landing contacts caused by the existing manufacturing process.

According to one aspect of the present disclosure, a semiconductor structure is provided. The semiconductor structure includes a substrate, a source region, a drain region and a gate structure. The source region is located in the substrate. The drain region is located in the substrate. The gate structure is disposed on the substrate and located between the source region and the drain region, and includes a first sub-gate structure and a second sub-gate structure. The first sub-gate structure is adjacent to the source region and includes a first sub-gate insulating layer. The second sub-gate structure is adjacent to the drain region and includes a second sub-gate insulating layer. The second sub-gate insulating layer and the first sub-gate insulating layer are separated from each other. The first sub-gate insulating layer has a first thickness, and the second sub-gate insulating layer has a second thickness greater than the first thickness.

According to another aspect of the present disclosure, a semiconductor structure is provided. The semiconductor structure includes a substrate, a first transistor and a second transistor. The substrate has a first element area and a second element area. The first transistor is formed in the first element area of the substrate, and includes a first gate structure. The first gate structure includes a first sub-gate insulating layer and a second sub-gate insulating layer separated from each other. The first sub-gate insulating layer has a first thickness, and the second sub-gate insulating layer has a second thickness greater than the first thickness. The second transistor is formed in the second element area of the substrate, and includes a second gate structure. The second gate structure includes a second gate insulating layer having a third thickness substantially equal to the first thickness.

According to still another aspect of the present disclosure, a method for fabricating a semiconductor structure is provided. The method includes the following steps. First, a substrate is provided. The substrate includes a first element area and a second element area. Then, a first transistor and a second transistor are respectively formed in the first element area and the second element area of the substrate. The first transistor includes a first gate structure. The first gate structure includes a first sub-gate insulating layer and a second sub-gate insulating layer separated from each other. The first sub-gate insulating layer has a first thickness, and the second sub-gate insulating layer has a second thickness greater than the first thickness. The second transistor includes a second gate structure. The second gate structure includes a second gate insulating layer. The first sub-gate insulating layer and the second gate insulating layer are formed by patterning the same gate insulation material layer.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a cross-sectional view of a semiconductor structure according to one embodiment of the present disclosure.

FIG. 2 is a cross-sectional view of a semiconductor structure according to another embodiment of the present disclosure.

FIG. 3 is a cross-sectional view of a semiconductor structure according to still another embodiment of the present disclosure.

FIG. 4 is a cross-sectional view of a semiconductor structure according to a further embodiment of the present disclosure.

FIG. 5 is a flowchart of a method for fabricating the semiconductor structure of FIG. 2.

FIG. 6 is a flowchart of a method for fabricating the semiconductor structure of FIG. 4.

### DETAILED DESCRIPTION

Each embodiment of the present disclosure will be described in detail hereinafter, and illustrated with drawings. In addition to these detailed descriptions, the disclosure may be broadly implemented in other embodiments, and any easily substituted, modified, or equivalent variations of the described embodiments are included within the scope of the present disclosure, which is subject to the scope of the claims thereafter. In the description of the specification, many specific details and examples of embodiments are provided in order to provide the reader with a more complete understanding of the disclosure; however, these specific details and examples of embodiments should not be considered as limitations of the disclosure. In addition, well-known steps or elements are not described in detail to avoid unnecessary limitations of the present disclosure.

It should be noted that the drawings of the present disclosure are simplified in order to clearly illustrate the contents of the embodiments and to highlight the features of the present disclosure, and the dimensions on the drawings are not drawn to the same scale as the actual product. Accordingly, the specification and the drawings are for the purpose of describing the embodiments only and are not intended to limit the scope of the disclosure. Identical or similar element symbols are used to represent identical or similar elements.

In addition, the terms such as “first”, “second”, “third”, etc. used in the specification and the claims are for the purpose of distinguishing different elements, and they do not imply and represent any previous sequence of the elements, nor do they represent the sequence of an element and another element, or the sequence of the manufacturing method, and the use of these terms is only for the purpose of making a clear distinction between an element with a certain name and another element with the same name.

Furthermore, the term “thickness” as used herein, if not otherwise specified, refers to a straight distance between the upper and lower surfaces of the referred element structure (e.g., an insulating layer).

Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Besides, for the sake of description, the terms such as “underneath”, “below”, “under”, “above”, “over”, “on”, and other spatial relative terms are used to describe the relationship between one element or feature and other element(s) or feature(s) as shown in the drawings. The spatial relative term is intended to cover different orientations of the element in use or operation, in addition to the orientation shown in the drawings. The element may be oriented in other ways, such as rotated 90 degrees or in other orientations, and again, the spatial relative term used herein may be interpreted accordingly.

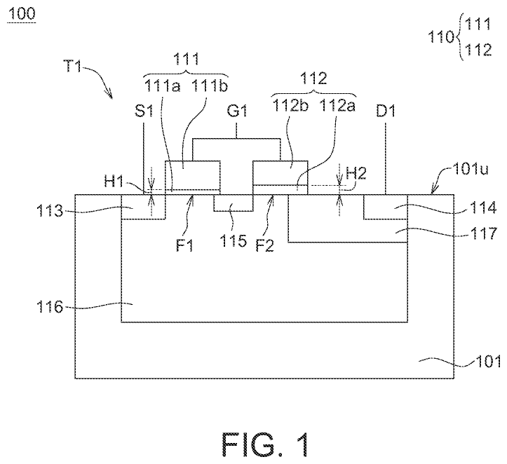

FIG. 1 is a cross-sectional view of a semiconductor structure 100 according to one embodiment of the present disclosure. Referring to FIG. 1, the semiconductor structure 100 may include a substrate 101, a gate structure 110, a source region 113 and a drain region 114. The source region 113 and the drain region 114 are located in the substrate 101. The gate structure 110 is disposed on the substrate 101 and located between the source region 113 and the drain region 114. The gate structure 110, the source region 113 and the drain region 114 may form a transistor T1, and may be used as being a gate G1, a source S1, and a drain D1, respectively, via contact plugs (not shown) to receive an externally applied voltage.

The gate structure 110 may include a first sub-gate structure 111 and a second sub-gate structure 112. The first sub-gate structure 111 is adjacent to the source region 113; in contrast, the second sub-gate structure 112 is adjacent to the drain region 114. In addition, the first sub-gate structure 111 and the second sub-gate structure 112 are separated from each other. The first sub-gate structure 111 may include a first sub-gate insulating layer 111a and a first sub-gate electrode layer 111b formed on the first sub-gate insulating layer 111a. The second sub-gate structure 112 may include a second sub-gate insulating layer 112a and a second sub-gate electrode layer 112b formed on the second sub-gate insulating layer 112a.

In one embodiment, the semiconductor structure 110 may further include a connection region 115. The connection region 115 is located in the substrate 111 and connected to the first sub-gate insulating layer 111a and the second sub-gate insulating layer 112a. The connection region 115 may be a heavily doped region, a lightly doped region, or a well region, and may have the same conductivity type as the source region 113 and the drain region 114. For example, when the conductivity type of the source region 113 and the drain region 114 is N-type, the connection region 115 may be heavily doped or lightly doped with an N-type dopant, or form an N-type well region.

In one embodiment, the semiconductor structure 100 may further include a well region 116. The well region 116 is located in the substrate 101, and the source region 113, the drain region 114 and the connection region 115 are located in the well region 116. The well region 116 may have a different conductivity type than the source region 113 and the drain region 114. For example, when the conductivity type of the source region 113 and the drain region 114 is N-type, the well region 116 may be doped with a P-type dopant.

In one embodiment, the semiconductor structure 100 may further include a drift region 117. The drift region 117 is located in the well region 116, the drain region 114 is located in the drift region 117, and the second sub-gate structure 112 is located on an intersection of the well region 116 and the drift region 117. The drift region 117 may have the same conductivity type as the drain region 114 and be lightly doped compared to the drain region 114. For example, when the conductive type of the drain region 114 is N-type, the drift region 117 may be lightly doped with an N-type dopant.

The first sub-gate insulating layer 111a and the second sub-gate insulating layer 112a may have different thicknesses. Further, the first sub-gate insulating layer 111a may have a first thickness H1, and the second sub-gate insulating layer 112a may have a second thickness H2 greater than the first thickness H1. Since the high voltage is typically applied to the drain region 114, the second sub-gate insulating layer 112a closer to the drain region 114 may be formed with a thicker thickness to prevent the second sub-gate insulating layer 112a from breaking due to the high voltage and thus adversely affecting the device characteristics. In addition, the first sub-gate insulating layer 111a that is farther away from the drain region 114 may be formed with a thinner thickness, so that the desired switching current and a better gate control capability may be maintained, thereby improving the electrical performance of the device.

Furthermore, when viewed horizontally from a cross-section of the semiconductor structure 100 (the upper surface 101u extending horizontally and perpendicular to the substrate 101), i.e., when viewed from the drawing of FIG. 1, the upper surface of the first sub-gate electrode layer 111b and the upper surface of the second sub-gate electrode layer 112b are substantially coplanar. In other words, the first sub-gate electrode layer 111b and the second sub-gate electrode layer 112b do not have a height difference, and therefore when contact plugs (not shown) are formed connecting to the first sub-gate electrode layer 111b and to the second sub-gate electrode layer 112b, there is no landing contact problem.

In one embodiment, the lower surface F1 of the first sub-gate insulating layer 111a and the lower surface F2 of the second sub-gate insulating layer 112a may be located at the upper surface 101u of the substrate 101. In other words, when viewed horizontally from a cross-section of the semiconductor structure 100 (the upper surface 101u extending horizontally and perpendicular to the substrate 101), i.e., when viewed from the drawing of FIG. 1, the lower surface F1 of the first sub-gate insulating layer 111a and the lower surface F2 of the second sub-gate insulating layer 112a may be substantially coplanar with the upper surface 101u of the substrate 101. In the embodiment, a first thickness H1 of the first sub-gate insulating layer 111a may be the same as the thickness of a gate insulating layer of a low-voltage transistor, and a second thickness H2 of the second sub-gate insulating layer 112a may be the same as the thickness of a gate insulating layer of an I/O transistor. For example, if the low-voltage transistor is a core device in a core area of a semiconductor structure, the first thickness H1 of the first sub-gate insulating layer 111a may be less than or equal to 25 angstroms (Å); and if the I/O transistor is an I/O device in an I/O area of the semiconductor structure, the second thickness H2 of the second sub-gate insulating layer 112a may be less than or equal to 40 angstroms (Å).

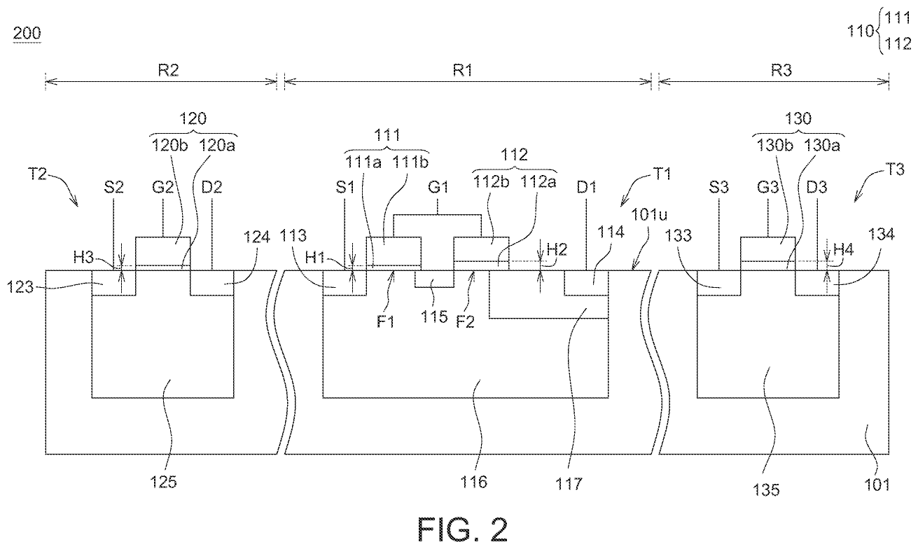

In detail, referring to FIG. 2, a cross-sectional view of a semiconductor structure 200 according to another embodiment of the present disclosure is shown. The semiconductor structure 200 may be a composite semiconductor structure in which the substrate 101 may have a first element area R1, a second element area R2, and a third element area R3. It should be understood that the relative positions of the first element area R1, the second element area R2, and the third element area R3 as depicted in FIG. 2 are for illustrative purposes only, and are not intended to limit the present disclosure. Different semiconductor elements, such as a first transistor T1, a second transistor T2, and a third transistor T3, may be disposed in these element areas R1-R3, respectively. The relevant configuration of the first transistor T1 has been described in connection with FIG. 1 and will not be repeated herein.

The first element area R1, the second element area R2, and the third element area R3 may respectively have different operating voltage ranges. In one embodiment, the second element area R2 may be a low voltage area, and the second transistor T2 may be a low-voltage transistor, such as a core device. The second transistor T2 may include a second gate structure 120, a source region 123, and a drain region 124. The second gate structure 120 is disposed on the substrate 101 and located between the source region 123 and the drain region 124. The source region 123 and the drain region 124 may be formed in a well region 125. The second gate structure 120, the source region 123, and the drain region 124 may be used as being a gate G2, a source S2, and a drain D2, respectively, via contact plugs (not shown) to receive an externally applied voltage. The second gate structure 120 may include a second gate insulating layer 120a and a second gate electrode layer 120b formed on the second gate insulating layer 120a.

The first sub-gate insulating layer 111a of the first gate structure 110 of the first transistor T1 and the second gate insulating layer 120a of the second gate structure 120 of the second transistor T2 may be the same patterned film layer. That is, the first sub-gate insulating layer 111a and the second gate insulating layer 120a may be fabricated in the same manufacturing process such that the first thickness H1 of the first sub-gate insulating layer 111a is substantially equal to the third thickness H3 of the second gate insulating layer 120a, for example, being less than or equal to 25 angstroms (Å).

The third element area R3 may be a high voltage area, and the third transistor T3 may be an I/O transistor. The third transistor T3 may include a third gate structure 130, a source region 133, and a drain region 134. The third gate structure 130 is disposed on the substrate 101 and located between the source region 133 and the drain region 134. The source region 133 and the drain region 134 may be formed in a well region 135. The third gate structure 130, the source region 133, and the drain region 134 may be used as being a gate G3, a source S3, and a drain D3, respectively, via contact plugs (not shown) to receive an externally applied voltage. The third gate structure 130 may include a third gate insulating layer 130a and a third gate electrode layer 130b formed on the third gate insulating layer 130a.

The second sub-gate insulating layer 112a of the first gate structure 110 of the first transistor T1 and the third gate insulating layer 130a of the third gate structure 130 of the third transistor T3 may be the same patterned film layer. That is, the second sub-gate insulating layer 112a and the third gate insulating layer 130a may be fabricated in the same manufacturing process such that the second thickness H2 of the second sub-gate insulating layer 112a is substantially equal to the fourth thickness H4 of the third gate insulating layer 130a, for example, being less than or equal to 40 angstroms (Å).

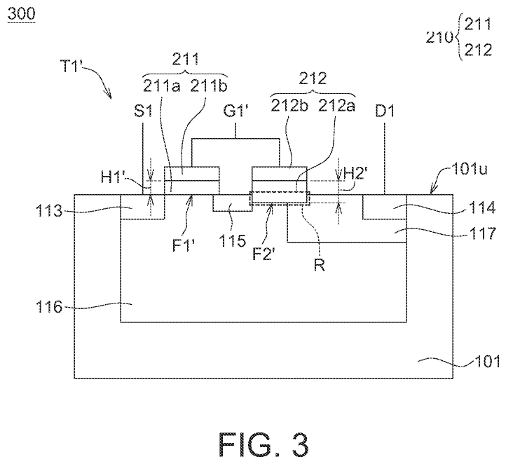

FIG. 3 is a cross-sectional view of a semiconductor structure 300 according to still another embodiment of the present disclosure. The semiconductor structure 300 of FIG. 3 is mostly similar to the semiconductor structure 100 of FIG. 1, except that the difference is in the gate structure 210 of the transistor T1′. The gate structure 210, the source region 113, and the drain region 114 of the transistor T1′ may be used as being a gate G1′, a source S1, and a drain D1, respectively, via contact plugs (not shown) to receive an externally applied voltages.

The gate structure 210 may include a first sub-gate structure 211 and a second sub-gate structure 212. The first sub-gate structure 211 is adjacent to the source region 113; in contrast, the second sub-gate structure 212 is adjacent to the drain region 114. In addition, the first sub-gate structure 211 and the second sub-gate structure 212 are separated from each other. The first sub-gate structure 211 may include a first sub-gate insulating layer 211a and a first sub-gate electrode layer 211b formed on the first sub-gate insulating layer 211a. The second sub-gate structure 212 may include a second sub-gate insulating layer 212a and a second sub-gate electrode layer 212b formed on the second sub-gate insulating layer 212a.

Similar to the transistor T1 of FIG. 1, the second thickness H2′ of the second sub-gate insulating layer 212a may be greater than the first thickness H1′ of the first sub-gate insulating layer 211a. Furthermore, the first thickness H1′ of the first sub-gate insulating layer 211a may be greater than the first thickness H1 in FIG. 1, and the second thickness H2′ of the second sub-gate insulating layer 212a may be greater than the second thickness H2 in FIG. 1. Accordingly, compared to the transistor T1 of FIG. 1, the transistor T1′ may withstand a higher voltage value.

Herein, the substrate 101 may have a recess portion R recessed from the upper surface 101u. The lower surface F1′ of the first sub-gate insulating layer 211a may be located at the upper surface 101u of the substrate 101, and the second sub-gate insulating layer 212a may be formed in the recess portion R such that the lower surface F2′ of the second sub-gate insulating layer 212a is located below the upper surface 101u of the substrate 101. Accordingly, the second sub-gate insulating layer 212a may have a second thickness H2′ greater than that of FIG. 1 to withstand a higher voltage. In addition, due to the downwardly-recessed recess portion R formed in the substrate 101, even if the thickness of the second sub-gate insulating layer 212a is thicker, there will not be a height difference between the second sub-gate electrode layer 212b and the first sub-gate electrode layer 211b, preventing landing contact problem.

In one embodiment, the first thickness H1′ of the first sub-gate insulating layer 211a may be the same as the thickness of the gate insulating layer of an I/O transistor, and the second thickness H2′ of the second sub-gate insulating layer 212a may be thicker than the thickness of the gate insulating layer of the I/O transistor to withstand a higher voltage. For example, if the I/O transistor is an I/O device in the I/O area of the semiconductor structure, the first thickness H1′ of the first sub-gate insulating layer 211a may be less than or equal to 40 angstroms (Å), and the second thickness H2′ of the second sub-gate insulating layer 212a may be greater than 40 angstroms (Å). In other embodiments, the first thickness H1′ of the first sub-gate insulating layer 211a may be the same as the thickness of the gate insulating layer of the core device in the core area of the semiconductor structure, for example, being less than or equal to 25 angstroms (Å); and the second thickness H2′ of the second sub-gate insulating layer 212a may be greater than the thickness of the I/O transistor, for example, being greater than 40 angstroms (Å), to withstand a higher voltage.

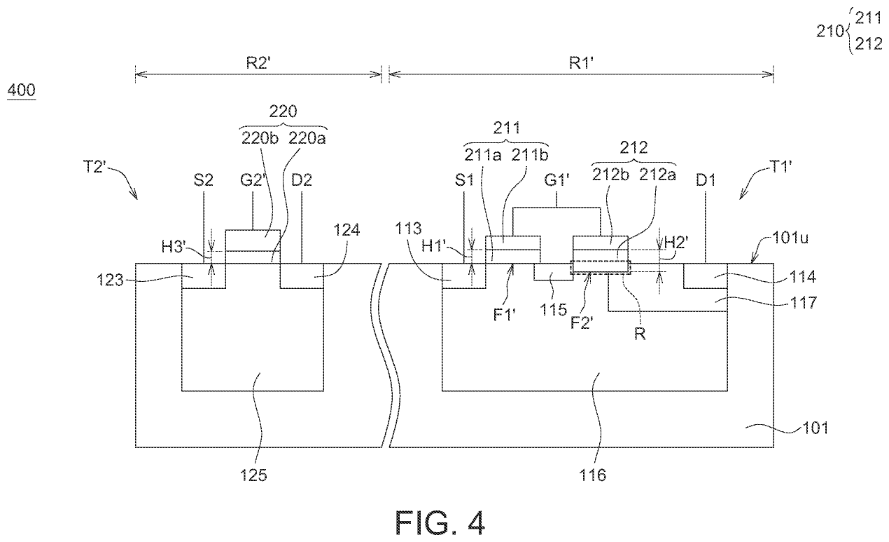

In detail, referring to FIG. 4, a cross-sectional view of a semiconductor structure 400 according to a further embodiment of the present disclosure is shown. The semiconductor structure 400 may be a composite semiconductor structure in which the substrate 101 may have at least a first element area R1′ and a second element area R2′. It should be understood that the relative positions of the first element area R1′ and the second element area R2′ depicted in FIG. 4 are for illustrative purposes only, and are not intended to limit the present disclosure. Different semiconductor elements, such as a first transistor T1′ and a second transistor T2′, may be disposed in these element areas R1-R2, respectively. The relevant configuration of the first transistor T1′ has been described in connection with FIG. 3 and will not be repeated herein. The first transistor T1′ may be a high-voltage transistor, and the first transistor T1′ may withstand a higher voltage value compared to the I/O transistor or the transistor T1 of FIG. 1.

The first element area R1′ and the second element area R2′ may respectively have different operating voltage ranges. In one embodiment, the second element area R2′ may be a high voltage area, and the second transistor T2′ may be an I/O transistor. In another embodiment, the second element area R2′ may be a low voltage area, and the second transistor T2′ may be a low-voltage transistor, such as a core device. The second transistor T2′ may include a second gate structure 220, a source region 123, and a drain region 124. The second gate structure 220 is disposed on the substrate 101 and located between the source region 123 and the drain region 124. The source region 123 and the drain region 124 may be formed in a well region 125. The second gate structure 220, the source region 123, and the drain region 124 may be used as being a gate G2′, a source S2, and a drain D2, respectively, via contact plugs (not shown) to receive an externally applied voltage. The second gate structure 220 may include a second gate insulating layer 220a and a second gate electrode layer 220b formed on the second gate insulating layer 220a.

The first sub-gate insulating layer 211a of the first gate structure 210 of the first transistor T1′ and the second gate insulating layer 220a of the second gate structure 220 of the second transistor T2′ may be the same patterned film layer. That is, the first sub-gate insulating layer 211a and the second gate insulating layer 220a may be fabricated in the same manufacturing process such that the first thickness H1′ of the first sub-gate insulating layer 211a is substantially equal to the third thickness H3′ of the second gate insulating layer 220a. For example, if the second transistor T2′ is an I/O transistor, the first thickness H1′ may be less than or equal to 40 angstroms (Å); if the second transistor T2′ is a core device, the first thickness H1′ may be less than or equal to 25 angstroms (Å).

With respect to the second sub-gate insulating layer 212a of the first gate structure 210 of the first transistor T1′, after the step of forming the recess portion R of the substrate 101, then the second sub-gate insulating layer 212a with thickness thicker than the first thickness H1′ may be formed.

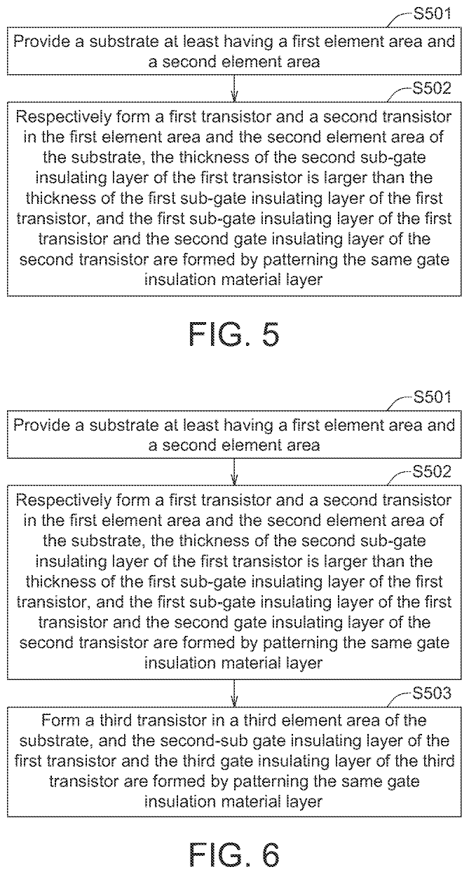

FIG. 5 is a flowchart of a method for fabricating the semiconductor structure 200 of FIG. 2. FIG. 6 is a flowchart of a method for fabricating the semiconductor structure 400 of FIG. 4. FIGS. 5 and 6 briefly illustrate the method for fabricating the semiconductor structures 200, 400, and it should be understood that the method for fabricating the semiconductor devices 200, 400 may also include other steps available in the art.

Referring to FIG. 5 and FIG. 6, as shown in step S501, a substrate 101 is provided. The substrate 101 at least includes a first element area R1, R1′ and a second element area R2, R2′. Then, as shown in step S502, a first transistor T1, T1′ and a second transistor T2, T2′ are respectively formed in the first element area R1, R1′ and the second element area R2, R2′ of the substrate 101. The first gate structure 110, 210 of the first transistor T1, T1′ includes a first sub-gate structure 111, 211 and a second sub-gate structure 112, 212 separated from each other. The first sub-gate insulating layer 111a, 211a of the first sub-gate structure 111, 211 has a first thickness H1, H1′, and the second sub-gate insulating layer 112a, 212a of the second sub-gate structure 112, 212 has a second thickness H2, H2′. The second thickness H2, H2′ is greater than the first thickness H1, H1′. The second gate structure 120, 220 of the second transistor T2, T2′ includes a second gate insulating layer 120a, 220a. The first sub-gate insulating layer 111a, 211a and the second gate insulating layer 120a, 220a are formed by patterning the same gate insulation material layer.

Referring to FIG. 6, the method further includes step S503, a third transistor T3 is formed in a third element area R3 of the substrate 101. The third gate structure 130 of the third transistor T3 includes a third gate insulating layer 130a. The second sub-gate insulating layer 112a and the third gate insulating layer 130a are formed by patterning the same gate insulation material layer.

As described hereinabove, the present disclosure prevents the second sub-gate insulating layer from breaking due to the high voltage, which adversely affects the characteristics of the device, by forming a thicker thickness of the second sub-gate insulating layer closer to the drain region. The present disclosure also enhances the electrical performance of the device by forming a thinner thickness of the first sub-gate insulating layer farther away from the drain region, which preserves the desired switching current and the better gate control capability. In addition, the first sub-gate insulating layer and the second sub-gate insulating layer are separated from each other and fabricated separately to avoid landing contact problems between the first sub-gate electrode layer and the second sub-gate electrode layer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure comprising:
a substrate;
a source region located in the substrate;
a drain region located in the substrate; and
a gate structure disposed on the substrate and located between the source region and the drain region, the gate structure comprising:
a first sub-gate structure adjacent to the source region, the first sub-gate structure comprising a first sub-gate insulating layer; and
a second sub-gate structure adjacent to the drain region, the second sub-gate structure comprising a second sub-gate insulating layer, the second sub-gate insulating layer and the first sub-gate insulating layer separated from each other;
wherein the first sub-gate insulating layer has a first thickness, the second sub-gate insulating layer has a second thickness, and the second thickness is greater than the first thickness.

2. The semiconductor structure according to claim 1, further comprising a connection region located in the substrate and connected to the first sub-gate insulating layer and the second sub-gate insulating layer.

3. The semiconductor structure according to claim 2, further comprising a well region located in the substrate, the source region, the drain region and the connection region located in the well region, wherein the well region has a first conductivity type, and the source region, the drain region and the connection each has a second conductivity type different from the first conductivity type.

4. The semiconductor structure according to claim 3, further comprising a drift region located in the well region, the drain region located in the drift region, the second-sub gate structure located on an intersection of the well region and the drift region, wherein the drift region has the second conductivity type.

5. The semiconductor structure according to claim 1, wherein the substrate has an upper surface extending horizontally, and a lower surface of the first sub-gate insulating layer and a lower surface of the second sub-gate insulating layer are located at the upper surface of the substrate.

6. The semiconductor structure according to claim 1, wherein the substrate has an upper surface extending horizontally and a recess portion recessed from the upper surface, a lower surface of the first sub-gate insulating layer is located at the upper surface of the substrate, and the second sub-gate insulating layer is formed in the recess portion such that a lower surface of the second sub-gate insulating layer is located below the upper surface of the substrate.

7. A semiconductor structure comprising:
a substrate having a first element area and a second element area;
a first transistor formed in the first element area of the substrate and comprising a first gate structure, the first gate structure comprising a first sub-gate insulating layer and a second sub-gate insulating layer separated from each other, the first sub-gate insulating layer having a first thickness, the second sub-gate insulating layer having a second thickness, the second thickness greater than the first thickness; and
a second transistor formed in the second element area of the substrate and comprising a second gate structure, the second gate structure comprising a second gate insulating layer, the second gate insulating layer having a third thickness, the third thickness substantially equal to the first thickness.

8. The semiconductor structure according to claim 7, wherein the first sub-gate insulating layer and the second gate insulating layer are the same patterned film layer.

9. The semiconductor structure according to claim 7, wherein the first transistor is a high-voltage transistor, and the second transistor is a low-voltage transistor.

10. The semiconductor structure according to claim 9, wherein the third thickness of the second gate insulating layer of the low-voltage transistor is less than or equal to 25 angstroms (Å).

11. The semiconductor structure according to claim 7, wherein the first transistor is a high-voltage transistor, and the second transistor is an I/O transistor.

12. The semiconductor structure according to claim 11, wherein the third thickness of the second gate insulating layer of the I/O transistor is less than or equal to 40 angstroms (Å).

13. The semiconductor structure according to claim 11, wherein the second thickness of the second sub-gate insulating layer of the first transistor is greater than 40 angstroms (Å).

14. The semiconductor structure according to claim 7, wherein the substrate further has a third element area, the semiconductor structure further comprises a third transistor formed in the third element area of the substrate and comprising a third gate structure, the third gate structure comprises a third gate insulating layer, and the third gate insulating layer has a fourth thickness substantially equal to the second thickness.

15. The semiconductor structure according to claim 14, wherein the second sub-gate insulating layer and the third gate insulating layer are the same patterned film layer.

16. The semiconductor structure according to claim 14, wherein the second transistor is a low-voltage transistor, and the third transistor is an I/O transistor.

17. The semiconductor structure according to claim 16, wherein the third thickness of the second gate insulating layer of the low-voltage transistor is less than or equal to 25 angstroms (Å), and the fourth thickness of the third gate insulating layer of the I/O transistor is less than or equal to 40 angstroms (Å).

18. The semiconductor structure according to claim 7, wherein the first transistor further comprises a source region, a drain region and a connection region located in the substrate, the first sub-gate insulating layer is adjacent to the source region, the second sub-gate insulating layer is adjacent to the drain region, and the connection region is connected to the first sub-gate insulating layer and the second sub-gate insulating layer.

19. The semiconductor structure according to claim 18, wherein the first transistor further comprises a well region located in the substrate, the source region, the drain region and the connection region are located in the well region, the well region has a first conductivity type, and the source region, the drain region and the connection each has a second conductivity type different from the first conductivity type.

20. The semiconductor structure according to claim 19, the first transistor further comprises a drift region located in the well region, the drain region is located in the drift region, the second-sub gate insulating layer is located on an intersection of the well region and the drift region, and the drift region has the second conductivity type.

21. The semiconductor structure according to claim 7, wherein the substrate has an upper surface extending horizontally, and a lower surface of the first sub-gate insulating layer and a lower surface of the second sub-gate insulating layer are substantially coplanar with the upper surface of the substrate when viewed horizontally from a cross-section perpendicular to the upper surface of the substrate.

22. The semiconductor structure according to claim 7, wherein the substrate has an upper surface extending horizontally, a lower surface of the first sub-gate insulating layer is substantially coplanar with the upper surface of the substrate when viewed horizontally from a cross-section perpendicular to the upper surface of the substrate, and a lower surface of the second sub-gate insulating layer is substantially lower than the upper surface of the substrate when viewed horizontally from the cross-section perpendicular to the upper surface of the substrate.

23. A method for fabricating a semiconductor structure comprising:
providing a substrate having a first element area and a second element area; and
respectively forming a first transistor and a second transistor in the first element area and the second element area of the substrate, wherein the first transistor comprises a first gate structure, the first gate structure comprises a first sub-gate insulating layer and a second sub-gate insulating layer separated from each other, the first sub-gate insulating layer has a first thickness, the second sub-gate insulating layer has a second thickness greater than the first thickness, the second transistor comprises a second gate structure, the second gate structure comprises a second gate insulating layer, and the first sub-gate insulating layer and the second gate insulating layer are formed by patterning the same gate insulation material layer.

24. The method according to claim 23, further comprising:
forming a third transistor in a third element area of the substrate, wherein the third transistor comprises a third gate structure, the third gate structure comprises a third gate insulating layer, and the second sub-gate insulating layer and the third gate insulating layer are formed by patterning the same gate insulation material layer.
